(19) United States
(12) Patent Application Publication
(10) Pub. No.: US 2011/0291098 A1
(43) Pub. Date: Dec. 1, 2011

(54) ORGANIC EL DISPLAY DEVICE, MOTHER SUBSTRATE OF ORGANIC EL DISPLAY DEVICE, AND METHOD OF TESTING ORGANIC EL DISPLAY DEVICE

(75) Inventor: Akinori Hayafuji, Yamagata (JP)

(73) Assignees: TOHOKU PIONEER CORPORATION, Tendo-shi, Yamagata (JP); PIONEER CORPORATION, Kawasaki-shi, Kanagawa (JP)

(21) Appl. No.: 13/147,431

(22) PCT Filed: Feb. 25, 2009
(86) PCT No.: PCT/JP2009/053431

§ 371 Date: Aug. 2, 2011

(51) Int. Cl. H01L 29/786; G01R 31/26

(52) U.S. Cl. 257/59; 257/72; 324/762.09; 257/E29.273

(57) ABSTRACT

A first resistance element (R1) and a second resistance element (R2) are added to a pixel circuit (1) in which an organic EL element (E1) is lighted and driven by a control TFT (T1) and a drive TFT (T2).

That is, an anode power supply wiring (a1) and a scanning wiring (s1) are connected through the first resistance element (R1), and a cathode power supply wiring (k1) and a data wiring (d1) are connected through the second resistance element (R2).

A test anode voltage (VH1) and a test cathode voltage (VL1) are applied respectively to the anode power supply wiring and the cathode power supply wiring, whereby pixels are lighted and driven. Consequently, whether or not the pixel circuit (1) is normally operated can be verified.

### TECHNICAL FIELD

The present invention relates to an active matrix type organic EL display device and particularly to a display device, which can be tested in a state of being a mother substrate before being mounted with a driver IC, and a method of testing the display device.

### BACKGROUND ART

Along with the spread of a portable telephone and a portable information terminal, there is a growing demand for a display device (hereinafter also referred to as a display panel) which has a high definition image display function and can realize the reduction of the thickness and power consumption, and there has been put to practical use a display panel using an organic EL (electroluminescence) element adopting such a characteristic that the organic EL element is a spontaneous light emitting element.

As the display panel using the organic EL element, there have been proposed a simple matrix type display panel in which EL elements are arranged in the form of a matrix and an active matrix type display panel in which an active element formed of TFT is added to each EL element arranged in the form of a matrix. The active matrix type display panel can realize the reduction of the power consumption in comparison with the simple matrix type display panel. The active matrix type display panel has the property of having less cross talk between pixels and is suitable especially for a high definition display constituting a large screen.

The display panel described above generally uses a large-sized mother substrate in order to enhance the mass productivity thereof, and there is employed so-called multi-piece means that sequentially applies film-forming process of a large number of organic EL elements, corresponding to individual display panels, and TFT to the mother substrate. A plurality of display panels are formed at a time on the mother substrate in this manner, and thereafter, the display panels are individually cut out by, for example, scribing.

The active matrix type display panel described above, for example, employs such a process of individually cutting out the display panels from the mother substrate, then mounting a driver circuit (IC) to the individual panels, and testing, in this state, lighting of an organic EL element including a pixel circuit formed of TFT.

According to the above process, when a defect of the organic EL element including the pixel circuit is found at the time of the lighting test, the process of mounting the driver circuit is spoiled, and consequently this contributes to the increase in manufacturing cost.

Thus, it has been proposed to test the lighting of the organic EL element including the pixel circuit in each display panel in the state of being the mother substrate before cutting out each display panel or before mounting the driver IC, and this proposal is disclosed in the following Patent Documents 1 and 2, for example.
Patent Document 1: Japanese Patent Application Laid-Open No. 2008-58637
Patent Document 2: Japanese Patent Application Laid-Open No. 2008-52235

### DISCLOSURE OF INVENTION

### Problems to be Solved by the Invention

The Patent Document 1 discloses a constitution for testing lighting of a pixel circuit before mounting a driver IC to each display panel. According to this constitution, the individual display panels require terminals such as a power wire input pad, a power control wire input pad, a simple test control pad, and a margin wire input pad and a switch element provided for each line used at the time of testing.

The Patent Document 2 discloses a constitution for testing lighting of a pixel circuit in a state of being a mother substrate. According to this constitution, individual display panels to be divided each include a test circuit, and thus each display panel (small substrate) on the mother substrate can be independently tested. However, the number of terminals and wirings is increased inevitably, and each small substrate includes the test circuit; therefore, the circuit size is inevitably increased.

The present invention has been made in view of the above problems, and an object of the invention is to provide an organic EL display device, which can realize the test of lighting of a pixel circuit in a state of being a mother substrate with no driver IC mounted and does not require the provision of an extra test circuit for each small substrate, a mother substrate of the organic EL display device, and a method of testing the organic EL display device.

### Means for Solving the Problems

A display device, a mother substrate of the display device, and a method of testing the display device according to the present invention made for solving the above problems at least include configurations according to the following respective independent claims.

### [Claim 1]

A method of testing an organic EL display device which includes a plurality of pixels at least including an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring, a cathode of the organic EL element being connected to a cathode power supply wiring, wherein

the anode power supply wiring and the scanning wiring are connected through a first resistance element,

the cathode power supply wiring and the data wiring are connected through a second resistance element, and

a test anode voltage and a test cathode voltage are applied respectively to the anode power supply wiring and the cathode power supply wiring, whereby each of the pixels is lighted and driven.

### [Claim 3]

An organic EL display device including:

a plurality of pixels which at least include an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring,

wherein a cathode of the organic EL element is connected to a cathode power supply wiring,

the scanning wiring is connected to the anode power supply wiring through a first resistance element, and

the data wiring is connected to the cathode power supply wiring through a second resistance element.

### [Claim 7]

A mother substrate of an organic EL display device, wherein a plurality of organic EL display devices are formed on a single substrate, the organic EL display device including a plurality of pixels which at least include an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring,

a cathode of the organic EL element is connected to a cathode power supply wiring,

the scanning wiring is connected to the anode power supply wiring through a first resistance element, and

the data wiring is connected to the cathode power supply wiring through a second resistance element,

the mother substrate including:

a common anode power supply wiring to which one or more anode power supply wirings of each of the organic EL display devices are commonly connected;

a common cathode power supply wiring to which one or more cathode power supply wirings of each of the organic EL display devices are commonly connected;

a test anode terminal connected to the common anode power supply wiring; and

a test cathode terminal connected to the common cathode power supply wiring.

### [Claim 9]

A method of testing an organic EL display device which includes a plurality of pixels at least including an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring, a cathode of the organic EL element being connected to a cathode power supply wiring, wherein

one electrode of a capacitative element is connected to the gate of the drive TFT,

a test signal is input from the other electrode of the capacitative element, and

a test anode voltage and a test cathode voltage are applied respectively to the anode power supply wiring and the cathode power supply wiring, whereby each of the pixels is lighted and driven.

### [Claim 10]

An organic EL display device including a plurality of pixels which at least include an organic EL element, a drive TFT in which any one of a source and a drain is connected to an anode of the organic EL element, and the other of the source and the drain is connected to an anode power supply wiring, a control TFT in which any one of a source and a drain is connected to a gate of the drive TFT, the other of the source and the drain is connected to a data wiring, and a gate is connected to a scanning wiring, and a capacitative element of which one electrode is connected to the gate of the drive TFT,

wherein a cathode of the organic EL element is connected to a cathode power supply wiring, and

the other electrode of the capacitative element is connected to the anode power supply wiring outside the pixel.

### BRIEF DESCRIPTION OF THE DRAWINGS

FIG. 1 is a circuit configuration diagram showing a first example of a pixel circuit suitably utilized in a display device according to the present invention.

FIG. 2 is a schematic diagram showing an example of a mother substrate for use in formation of a large number of the display devices.

FIG. 3 is a circuit configuration diagram showing a second example of the pixel circuit suitably utilized in the display device according to the present invention.

FIG. 4 is a circuit configuration diagram showing a third example of the pixel circuit likewise.

FIG. 5 is a circuit configuration diagram showing a fourth example of the pixel circuit likewise.

FIG. 6 is a circuit configuration diagram showing a fifth example of the pixel circuit likewise.

FIG. 7 is a circuit configuration diagram showing a sixth example of the pixel circuit likewise.

FIG. 8 is a circuit configuration diagram showing a seventh example of the pixel circuit likewise.

FIG. 9 is a circuit configuration diagram showing an example in which wire is connected so that the pixel circuit shown in FIG. 8 can be lighted.

FIG. 10 is a schematic diagram showing an example of a mother substrate when the pixel circuit of FIG. 8 is used.

FIG. 11 is a schematic diagram showing an example of another mother substrate likewise.

FIG. 12 is a schematic diagram showing an example of a mother substrate which can be suitably used in a color display panel.

### EXPLANATION OF NUMERALS AND SYMBOLS

1 Pixel circuit
2 Display device (display panel)
3 Mother substrate
a1 Anode power supply wiring
Ac Common anode power supply wiring
At Test anode terminal
C1 Capacitative element (capacitor)
d1 Data wiring
E1 Organic EL element
k1 Cathode power supply wiring
Kc Common cathode power supply wiring
Kt Test cathode terminal
Ki Test capacitive terminal
s1 Scanning wiring
SW1 Switching element
SW2 Switching element
R1 First resistance element
R2 Second resistance element
R3 to R8 Resistance element
T1 Control TFT
T2 Drive TFT
T3 to T7 TFT
VH1 Test anode voltage
VL1 Test cathode voltage

### BEST MODE FOR CARRYING OUT THE INVENTION

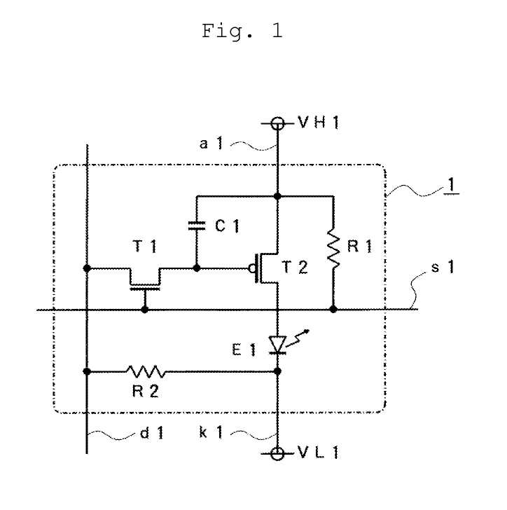

An organic EL display device, a mother substrate of the organic EL display device, and a method of testing the organic EL display device according to the present invention will be described based on the illustrated embodiment. FIG. 1 shows an example of a pixel circuit 1 constituting the organic EL display device, and this configuration is called a conductance control technique.

That is, a gate of a control TFT (T1) constituted of an n channel is connected to a scanning wiring s1, and a source of the control TFT is connected to a data wiring d1. Meanwhile, a drain of the control TFT is connected to a gate of a drive TFT (T2) constituted of a p channel, and, at the same time, connected to one electrode of a capacitor (capacitative element) C1 for charge retention.

Meanwhile, a source of the drive TFT is connected to the other electrode of the capacitative element C1, and, at the same time, connected to an anode power supply wiring a1. A drain of the drive TFT is connected to an anode of an organic EL element E1, and a cathode of the organic EL element E1 is connected to a cathode power supply wiring k1.

In the pixel circuit 1 shown in FIG. 1, when a scanning selection signal is supplied to the scanning wiring s1, the control TFT (T1) is in an on state. A data voltage supplied to the data wiring d1 at that time is held in the capacitative element C1 connected to the gate of the drive TFT (T2) through the TFT (T1).

The drive TFT (T2) applies an electric current, corresponding to the voltage held in the capacitative element C1, to the organic EL element E1, and the relevant element E1 is lighted. Then, scanning selection operation is terminated, and even when the control TFT (T1) is turned off, the drive TFT (T2) is operated so as to continue the lighting state of the organic EL element E1 by the voltage held in the capacitative element C1.

In the present embodiment, the pixel circuit 1 having the above configuration further includes a first resistance element R1 and a second resistance element R2. That is, the scanning wiring s1 is connected to the anode power supply wiring a1 through the first resistance element R1, and the data wiring d1 is connected to the cathode power supply wiring k1 through the second resistance element R2.

In the above pixel configuration, a test anode voltage VH1 and a test cathode voltage VL1 are applied to the anode power supply wiring a1 and the cathode power supply wiring k1, respectively (however, the value of VH1-VL1 is adapted to be a potential difference satisfactorily larger than a threshold voltage of the EL element E1), whereby the EL element E1 can be lighted.

That is, the VH1 is applied to the gate of the control TFT (T1) through the first resistance element R1, and the VL1 is applied to the source of the control TFT through the second resistance element R2. As a result, the control TFT is in the on state, and the level of the gate of the drive TFT (T2) is set to a level close to the VL1. Accordingly, the drive TFT is in the on state, and the EL element E1 can be lighted.

By virtue of the lighting of the EL element E1, it is verified that the control TFT (T1), the drive TFT (T2), the capacitative element C1, and the organic EL element E1 are normally operated. In this pixel configuration, an extra test circuit is not required, and it is possible to test the lighting of each pixel in such a state that a driver (IC) circuit for lighting and driving the EL element E1 is not mounted.

In the configuration shown in FIG. 1, an n-channel type is used as the control TFT, and a p-channel type is used as the drive TFT; however, they can be suitably selected. Accordingly, a circuit configuration may be adopted in which the source of the drive TFT (T2) is connected to the anode of the organic EL device, and the drain of the control TFT (T1) is connected to the gate of the drive TFT (T2).

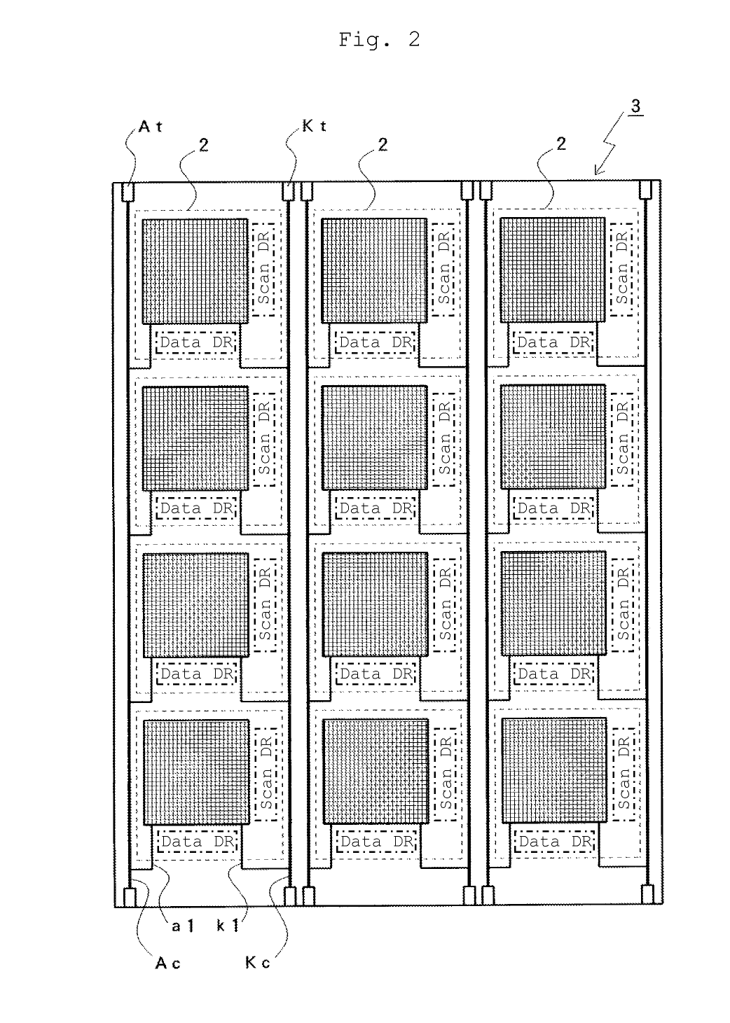

Hereinbefore, with regard to one pixel circuit, the method of testing the pixel circuit has been described. Actually, similar tests are collectively applied to a large-sized mother substrate 3 in which a large number of organic EL display devices (display panels) 2, constituted of the pixel circuits 1 arranged in the form of a matrix in vertical and horizontal directions, are formed in vertical and horizontal directions, as shown in FIG. 2.

That is, the example shown in FIG. 2 shows an embodiment of the mother substrate 3 in which the display panels 2 of 4×3 are simultaneously stacked and formed in the vertical and horizontal directions, and regions of each of the display panels 2 depicted by the chain lines as “data DR” and “scan DR” respectively show regions where a data driver IC and a scan driver IC are mounted after the display panel 2 is cut out from the mother substrate 3.

A portion shown by a lattice pattern occupying the majority of the area of each of the display penal 2 shows a light-emitting display portion formed by arranging the pixel circuits 1 shown in FIG. 1 in the form of a matrix in the vertical and horizontal directions.

In the mother substrate 3 shown in FIG. 2, common anode power supply wirings Ac commonly connecting the anode power supply wirings a1 drawn from the respective display panels 2 are aligned. In each of the display panels 2, the respective power supply wirings a1 in the pixel circuits 1 shown in FIG. 1 are assembled to be the anode power supply wiring a1 shown in FIG. 2.

In the example shown in the drawing, the anode power supply wirings a1 in the four display panels 2 in the vertical direction are connected to the common anode power supply wiring Ac. The common anode power supply wiring Ac is connected to a test anode terminal At the end of the mother substrate 3.

Further, in the mother substrate 3, common cathode power supply wirings Kc commonly connecting the cathode power supply wirings k1 drawn from the respective display panels 2 are aligned. In each of the display panels 2, the respective power supply wirings k1 in the pixel circuits 1 shown in FIG. 1 are assembled to be the cathode power supply wiring k1 shown in FIG. 2.

Similarly, the cathode power supply wirings k1 in the four display panels 2 in the vertical direction are connected to the common cathode power supply wiring Kc. The common cathode power supply wiring Kc is connected to a test cathode terminal Kt at the end of the mother substrate 3.

In the above configuration of the mother substrate 3, the test anode voltage VH1 is applied to the test anode terminal At, and the test cathode voltage VL1 is applied to the test cathode terminal Kt. As a result, the test anode voltage VH1 is applied to the respective display panels 2 through the common anode power supply wiring Ac, and the test cathode voltage VL1 is applied to the respective display panels 2 through the common cathode power supply wiring Kc.

In the individual display panels 2 on the mother substrate 3, the above-described pixel circuits 1 shown in FIG. 1 are arranged in the form of a matrix, and all the EL elements E1 constituting the pixels can be lighted by the operation of the first and second resistance elements R1 and R2. Accordingly, by virtue of the lighting of the EL elements E1 aligned in the respective display panels 2, it can be verified that the respective pixel circuits are normally operated.

In the configuration of the mother substrate 3 shown in FIG. 2, the display panels are cut out in units of the display panel, denoted by the reference numeral 2, after the termination of the lighting test. In the cut process, the common anode power supply wiring Ac and the common cathode power supply wiring Kc are removed.

In the above configuration of the mother substrate 3, the first and second resistance elements R1 and R2 do not necessarily have to be provided for each pixel circuit 1, unlike FIG. 1. That is, when the first resistance element R1 is connected to between the scanning wiring s1 and the anode power supply wiring a1 in units of the display panel 2, other pixel circuits commonly connected to the scanning wiring s1 share the first resistance element R1 at the time of testing, and the lighting operation is performed.

Similarly, when the second resistance element R2 is connected to between the data wiring d1 and the cathode power supply wiring k1 in units of the display panel 2, other pixel circuits commonly connected to the data wiring d1 share the second resistance element R2 at the time of testing, and the lighting operation is performed.

In the finished product of the display panel 2, even when the first and second resistance elements R1 and R2 exist in the pixel circuit 1, the lighting operation is not hampered. That is, the data wiring d1 and the scanning wiring s1 are driven respectively by the data driver IC and the scan driver IC, and each driver output is adopted to be a reference potential in a no-signal state. Accordingly, the data wirings d1 and the scanning wiring s1 are not in an open state, and erroneous lighting due to the first and second resistance elements R1 and R2 does not occur.

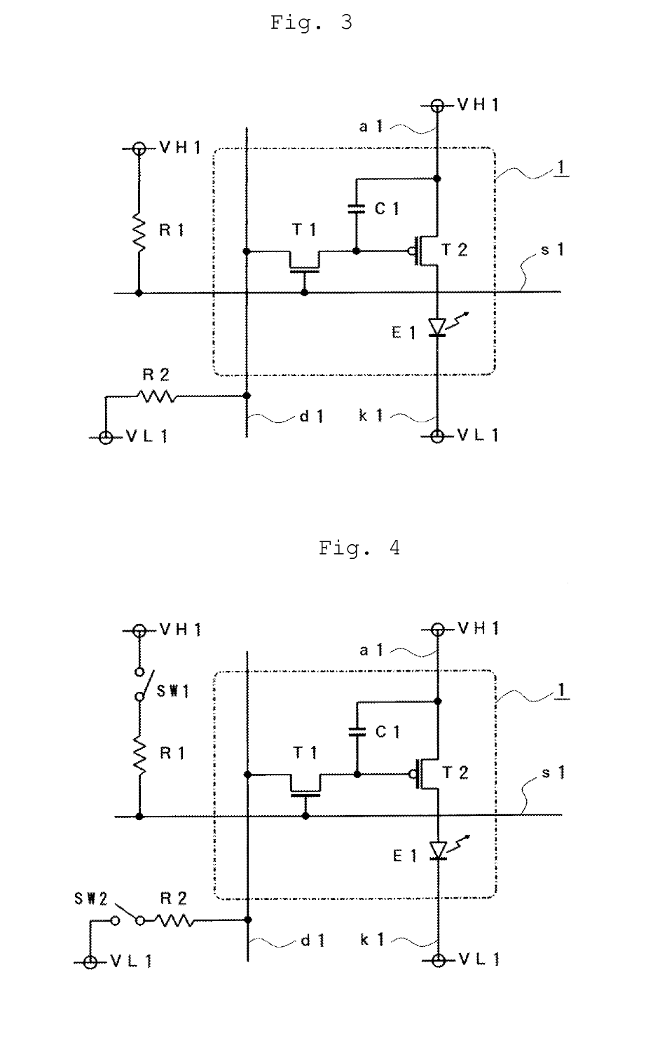

FIG. 3 shows an example in which the first and second resistance elements R1 and R2 are arranged outside the pixel circuit 1. In FIG. 3, components having the same functions as those shown in FIG. 1 are indicated by the same reference numerals, and the detailed description thereof will be omitted.

In the example shown in FIG. 3, the test anode voltage VH1 is supplied to the gate of the control TFT (T1) through the external first resistance element R1, and the test cathode voltage VL1 is supplied to the source of the control TFT (T1) through the external second resistance element R2.

As shown in FIG. 3, even when the first and second resistance elements R1 and R2 are arranged outside the pixel circuit 1, for the same reason as above, the first and second resistance elements R1 and R2 are not required to be arranged so as to correspond to each of the pixel circuits 1.

As shown in FIG. 3, even in the display panel 2 including the pixel circuit 1 externally provided with the first and second resistance elements R1 and R2, the lighting test in each of the pixel circuits 1 can be executed in the embodiment of the mother substrate 3 having the configuration shown in FIG. 2, and a similar operational effect can be obtained.

FIG. 4 shows another example in which the first and second resistance elements R1 and R2 are arranged outside the pixel circuit 1. Components having the same functions as those shown in FIGS. 1 and 3 are indicated by the same reference numerals, and thus the detailed description thereof will be omitted.

In the configuration shown in FIG. 4, a switching element, denoted by SW1, is serially inserted in the first resistance element R1 to which the test anode voltage VH1 is applied, and a switching element, denoted by SW2, is serially inserted in the second resistance element R2 to which the test cathode voltage VL1 is applied. The other configurations are similar to those in the example shown in FIG. 3.

According to the configuration shown in FIG. 4, the switching elements denoted by SW1 and SW2 are in an off state other than at the time of the lighting test of the circuit pixel 1, whereby it is possible to prevent any test voltage through the first and second resistance elements R1 and R2 from affecting the pixel circuit 1.

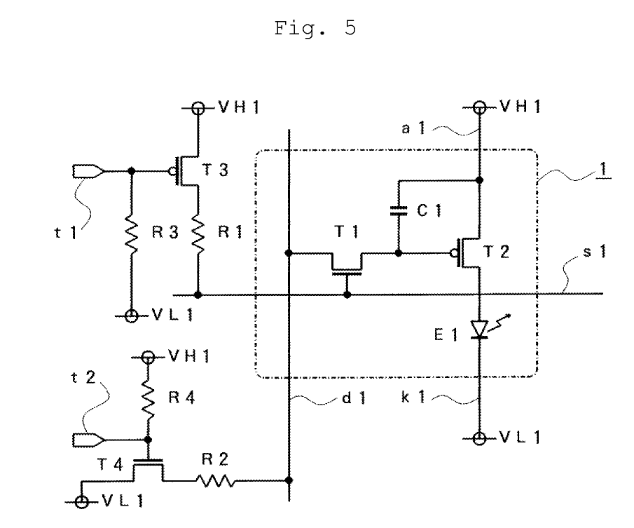

FIG. 5 shows an example in which the switching elements SW1 and SW2 shown in FIG. 4 are constituted of TFT. In this example, a p-channel type TFT (T3) is serially inserted in the first resistance element R1 to which the test anode voltage VH1 is applied, and the gate thereof is pulled down to the test cathode voltage VL1 through a resistance element R3.

Meanwhile, an n-channel type TFT (T4) is serially inserted in the second resistance R2 to which the test cathode voltage VL1 is applied, and the gate thereof is pulled up to the test anode voltage VH1 through a resistance element R4.

According to the configuration shown in FIG. 5, t1 connected to the gate of the TFT (T3) is set to a potential equivalent to the VH1, for example, other than at the time of the lighting test of the pixel circuit 1, and t2 connected to the gate of the TFT (T4) is set to a reference potential (ground) of a circuit, for example, whereby each of the TFTs can be brought in an off state. Consequently, it is possible to prevent any test voltage through the first and second resistance elements R1 and R2 from affecting the pixel circuit 1.

FIG. 6 shows another example in which the first and second resistance elements R1 and R2 are arranged in the pixel circuit 1. Components having the same functions as those shown in FIG. 1 are indicated by the same reference numerals, and thus the detailed description thereof will be omitted.

In the example shown in FIG. 6, a p-channel type TFT (T5) is inserted in between the drive TFT (T2) and the organic EL element E1. The gate of the TFT is connected to the side of the cathode of the organic EL element E1, that is, the cathode power supply wiring k1 through a resistance element R5.

In the pixel circuit 1 shown in FIG. 6, when the test anode voltage VH1 and the test cathode voltage VL1 are applied respectively to the anode power supply wiring a1 and the cathode power supply wiring k1, the TFT (T5) is in an on state, and the organic EL element E1 can be lighted. Consequently, it is verified that the pixel circuit 1 is normally operated.

When the operation as a display panel is performed, the TFT (T5) functions as a constant current element in the pixel circuit 1.

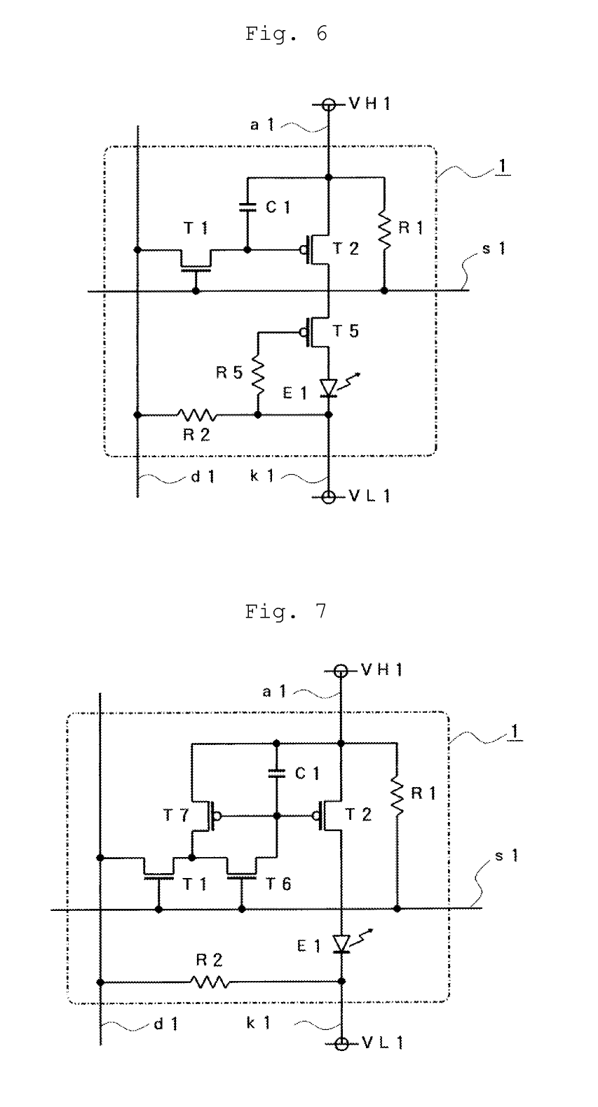

FIG. 7 shows still another example in which the first and second resistance elements R1 and R2 are arranged in the pixel circuit 1 and shows an example of a current mirror pixel circuit. In FIG. 7, components having the same functions as those shown in FIG. 1 are indicated by the same reference numerals, and thus the detailed description thereof will be appropriately omitted.

In the embodiment shown in FIG. 7, the drive TFT (T2) is operated so as to apply an electric current, corresponding to a gate voltage applied to a gate, to the organic EL element E1. A p-channel type TFT (T7) has the same characteristics as the drive TFT (T2), and the drive TFT (T2) and the TFT (T7) constitute a current mirror circuit through the drive TFT (T1) and an n-channel type TFT (T6) functioning as a switch.

When a scanning selection signal is supplied to the scanning wiring s1, both the TFT (T1) and the TFT (T6) are in the on state. A constant current supplied from the data wiring d1 at that time is supplied to the TFT (T7) through the control TFT (T1), and a voltage corresponding to a current value is held in the capacitative element C1 connected to a gate of the TFT (T7).

An electric current having the same value as an electric current applied to the TFT (T7) is applied to the drive TFT (T2) according to the voltage held in the capacitative element C1, and the organic EL element E1 is lighted. The scanning selection operation is terminated, and even when the TFT (T1) and the TFT (T6) are turned off, by virtue of the voltage held in the capacitative element C1, the drive TFT (T2) operates so as to continue the lighting state of the organic EL element E1.

Also in the pixel circuit shown in FIG. 7, the scanning wiring s1 is connected to the anode power supply wiring a1 through the first resistance element R1, and the data wiring d1 is connected to the cathode power supply wiring k1 through the second resistance element R2.

Accordingly, the test anode voltage VH1 and the test cathode voltage VL1 are applied respectively to the anode power supply wiring a1 and the cathode power supply wiring k1, whereby the EL element E1 can be lighted.

By virtue of the lighting of the EL element E1, it can be verified that the pixel circuit 1 is normally operated. Even in this pixel configuration, an extra test circuit is not required, and it is possible to test the lighting of each pixel in such a state that the driver (IC) circuit for lighting and driving the EL element E1 is not mounted.

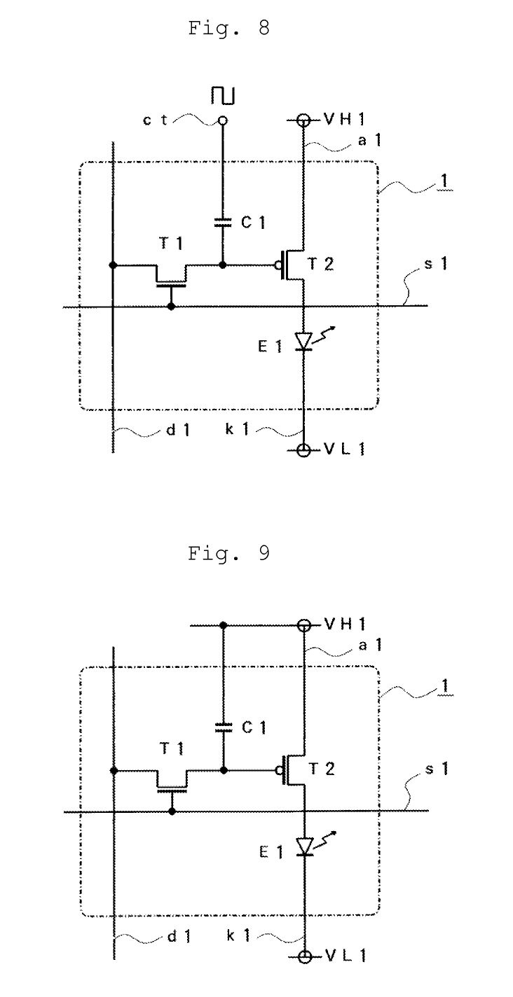

FIG. 8 and the subsequent drawings show another embodiment of an organic EL display device according to the present invention, which does not include the first and second resistance elements R1 and R2, a mother substrate of the organic EL display device, and a method of testing the organic EL display device.

In FIG. 8, components having the same functions as those shown in FIG. 1 are indicated by the same reference numerals, and thus the detailed description thereof will be omitted. In the embodiment shown in FIG. 8, one electrode of a capacitative element C1 in which the other electrode is connected to a gate of a drive TFT (T2) is separated from an anode power supply wiring a1 to be a test capacitive terminal ct.

In a pixel circuit 1 shown in FIG. 8, a test anode voltage VH1 and a test cathode voltage VL1 are applied respectively to the anode power supply wiring a1 and a cathode power supply wiring k1. A test signal such as a rectangular wave, a saw-tooth wave, and a sinusoidal wave is input to the test capacitive terminal ct in such a state, whereby the drive TFT (T2) intermittently performs an on-operation in synchronization with the frequency of the test signal, and an organic EL element E1 is intermittently lighted and driven. Consequently, it can be verified that the pixel circuit 1 is normally operated.

Also in the above pixel configuration, an extra test circuit is not required, and it is possible to test the lighting of each pixel in such a state that a driver (IC) circuit for lighting and driving the EL element E1 is not mounted.

In the pixel circuit 1 shown in FIG. 8, after the termination of the lighting test, an electrode on the side of the test capacitive terminal ct of the capacitative element C1 is connected to the anode electrode wiring a1 in a region outside the pixel circuit 1 as shown in FIG. 9. According to this constitution, one lighting pixel is formed.

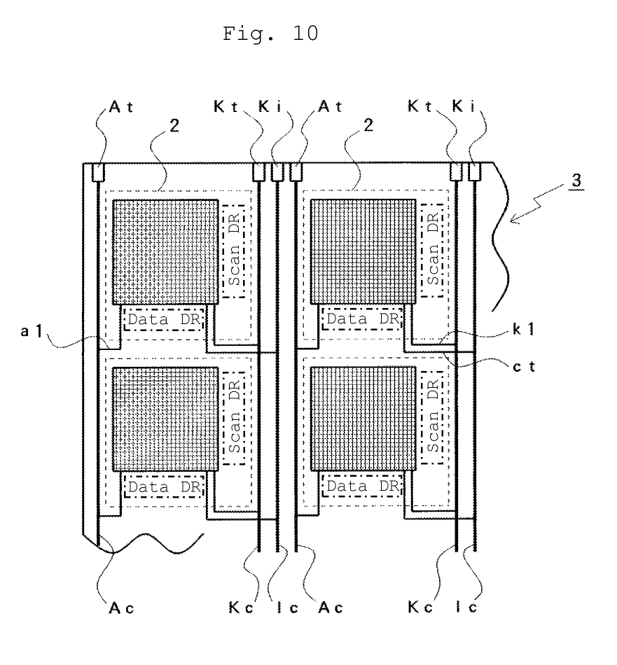

FIG. 10 shows a preferred embodiment of the mother substrate 3 for the display panels 2 in which the pixel circuits 1 of FIG. 8 arranged in the form of a matrix are formed and describes an example in which the lighting test of each of the pixel circuits 1 is executed for the mother substrate 3. In the mother substrate 3 shown in FIG. 10, formation regions of the display panel 2 of 2×2 in vertical and horizontal directions are shown. Components having the same functions as those of the mother substrate 3 shown in FIG. 2 are indicated by the same reference numerals, and thus the detailed description thereof will be omitted.

In the mother substrate 3 shown in FIG. 10, common test terminal wires Ic commonly connecting test capacitive terminals it drawn from the respective display panels 2 are further aligned. In the respective display panels 2 shown in FIG. 10, the respective test capacitive terminals ct in the pixel circuits 1 shown in FIG. 8 are assembled to be the test terminal wire ct shown in FIG. 10. The common test terminal wire Ic is connected to the test capacitive terminal Ki at the end of the mother substrate 3.

In the configuration of the mother substrate 3, the test anode voltage VH1 and the test cathode voltage VL1 are applied respectively to the test anode terminal At and the test cathode terminal Kt. The test signal such as a rectangular wave, a saw-tooth wave, and a sinusoidal wave is applied to the test capacitive terminal Ki as described above.

According to the above constitution, all the organic EL elements E1 aligned in each of the display panels 2 are intermittently lighted and driven in synchronization with the frequency of the test signal, and whether or not the pixel circuit 1 is normally operated can be verified.

Meanwhile, in the pixel circuit 1 shown in FIG. 8, even when the test capacitive terminal ct is connected to the cathode power supply wiring k1, the test anode voltage VH1 is applied to the anode power supply wiring a1, and a pulse signal is supplied to the cathode power supply wiring k1, the organic EL element E1 can be lighted similarly. By virtue of the lighting of the organic EL elements E1 due to this, it can be verified that the pixel circuit 1 is normally operated.

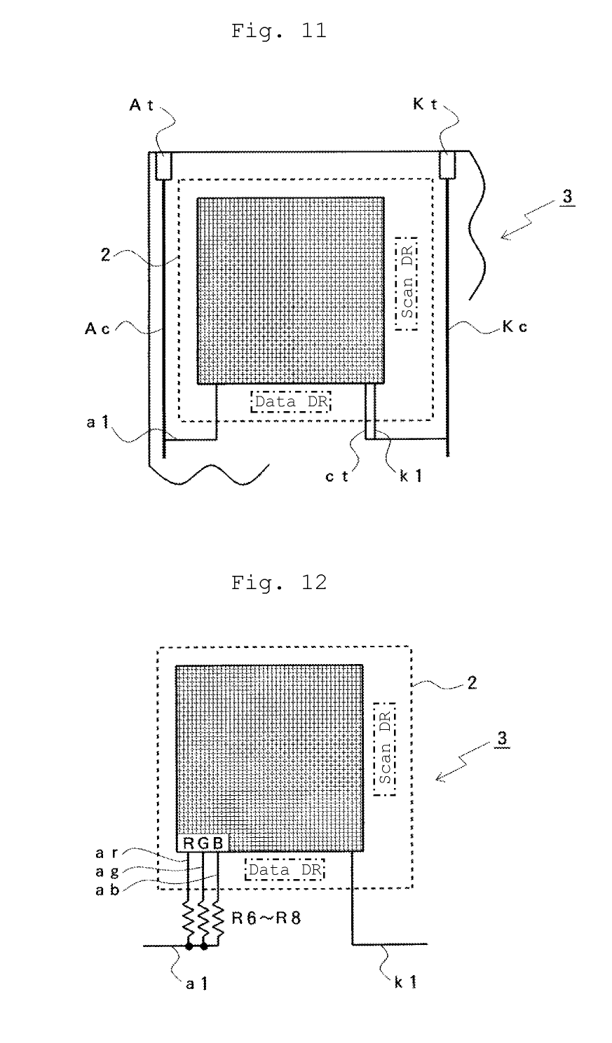

FIG. 11 shows a preferred embodiment of the mother substrate 3 when the test capacitive terminal ct shown in FIG. 8 is connected to the cathode power supply wiring k1. In the mother substrate 3 shown in FIG. 12, only a portion where one display panel 2 is formed is shown. Components having the same functions as those of the mother substrate 3 shown in FIG. 2 are indicated by the same reference numerals, and thus the detailed description thereof will be omitted.

In the mother substrate 3 shown in FIG. 11, the test capacitive terminals ct drawn from the pixel circuits of the respective display panels 2 are assembled to be the test capacitive terminal wire ct, and the test capacitive terminal wire ct is connected to the cathode power supply wiring k1 assembled in the display panel 2 outside the formation region of the display panel 2.

The cathode power supply wiring k1 is connected to the common cathode power supply wiring Kc on the mother substrate 3, and the common cathode power supply wiring Kc is connected to the test cathode terminal Kt at the end of the mother substrate 3.

In the configuration of the mother substrate 3 shown in FIG. 11, the test anode voltage VH1 is applied to the test anode terminal At, and a pulse signal is supplied to the test cathode terminal Kt, whereby the organic EL elements E1 aligned in the respective display panels 2 can be lighted and driven. Consequently, it can be verified whether or not the individual pixel circuits 1 aligned in the respective display panels 2 are normally operated.

Then, the display panels are cut out from the mother substrate 3 in units of the display panel, denoted by the reference numeral 2, after the above lighting test, and the test capacitive terminal wire ct and the cathode power wiring k1 are disconnected at this time.

FIG. 12 shows an example that can be suitably used in a mother substrate of a display panel which includes a plurality of organic EL elements having different light emitting colors and realizes color display, for example. In the mother substrate 3 shown in FIG. 12, only the formation region of one display panel 2 is shown. Components having the same functions as those of the mother substrate 3 shown in FIG. 2 are indicated by the same reference numerals, and thus the detailed description thereof will be omitted.

The example shown in FIG. 12 is suitably used when the organic EL elements emitting light of colors of R (red), G (green), and B (blue) are aligned as sub-pixels in the display panel 2, and one color display pixel is constituted of the three sub-pixels.

The sub-pixels have different light emitting efficiencies. For the light emitting efficiency of the EL element of each color that can be put to practical use at present, the light emitting efficiency of G is generally high, and the light emitting efficiencies of R and B are low. Accordingly, when the same drive voltage is supplied to each sub-pixel, it is difficult to obtain a normal color balance.

Thus, in the example shown in FIG. 12, anode power wirings ar, ag, and ab are provided for each sub-pixel of the same color, and resistance elements R6 to R8 are inserted for each color. That is, the anode power supply wirings ar, ag, and ab for each light emitting color are connected to the anode power supply wiring a1 through the resistance elements R6 to R8 for color balance adjustment, having a resistance value based on the characteristics of the organic EL elements of the above respective light emitting colors, and then connected to the common anode power supply wiring Ac.

In the above case, the color balance adjustment resistance may be inserted not in an anode power supply wiring of a sub-pixel having the lowest light emitting efficiency, but in an anode power supply wiring of a sub-pixel having a high light emitting efficiency.

The configuration shown in FIG. 12 can be used in the configuration of the mother substrate 3 shown in FIGS. 2, 10, and 11. The display panels are cut out from the mother substrate 3 in units of the display panel, denoted by the reference numeral 2, after the above lighting test, and the resistance elements R6 to R8 are cut and removed at this time.

In the configuration of the mother substrate 3 shown in FIG. 12, although the resistance elements R6 to R8 for color balance adjustment are provided outside the display panel denoted by the reference numeral 2, they may be provided inside the display panel 2. In this case, drive voltage sources different for each of R, G, and B are not required to be provided, and a display with a high color balance can be realized using a single common drive voltage source.

1. A method of testing an organic EL display device which comprises a plurality of pixels at least comprising an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring, a cathode of the organic EL element being connected to a cathode power supply wiring, wherein
the anode power supply wiring and the scanning wiring are connected through a first resistance element,
the cathode power supply wiring and the data wiring are connected through a second resistance element, and
a test anode voltage and a test cathode voltage are applied respectively to the anode power supply wiring and the cathode power supply wiring, whereby each of the pixels is lighted and driven.

2. The method of testing an organic EL display device according to claim 1, wherein a mother substrate formed with a plurality of the organic EL display devices comprises:
a common anode power supply wiring to which one or more anode power supply wirings of each of the organic EL display devices are commonly connected;
a common cathode power supply wiring to which one or more cathode power supply wirings of each of the organic EL display devices are commonly connected;
a test anode terminal connected to the common anode power supply wiring; and
a test cathode terminal connected to the common cathode power supply wiring, and
the test anode voltage and the test cathode voltage are applied respectively to the anode power supply wiring and the cathode power supply wiring, whereby each of the pixels is lighted and driven.

3. An organic EL display device comprising:
a plurality of pixels which at least comprise an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring,
wherein a cathode of the organic EL element is connected to a cathode power supply wiring,
the scanning wiring is connected to the anode power supply wiring through a first resistance element, and
the data wiring is connected to the cathode power supply wiring through a second resistance element.

4. The organic EL display device according to claim 3, wherein the first resistance element and the second resistance element are arranged in a pixel circuit.

5. The organic EL display device according to claim 3, wherein the first resistance element and the second resistance element are arranged outside a pixel circuit.

6. The organic EL display device according to claim 5, wherein switching elements are serially connected to the first resistance element and the second resistance element.

7. A mother substrate of an organic EL display device, wherein a plurality of organic EL display devices are formed on a single substrate, the organic EL display device comprising a plurality of pixels which at least comprise an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring,
a cathode of the organic EL element is connected to a cathode power supply wiring,
the scanning wiring is connected to the anode power supply wiring through a first resistance element, and
the data wiring is connected to the cathode power supply wiring through a second resistance element,
the mother substrate comprising:
a common anode power supply wiring to which one or more anode power supply wirings of each of the organic EL display devices are commonly connected;
a common cathode power supply wiring to which one or more cathode power supply wirings of each of the organic EL display devices are commonly connected;
a test anode terminal connected to the common anode power supply wiring; and
a test cathode terminal connected to the common cathode power supply wiring.

8. The mother substrate of an organic EL display device according to claim 7, wherein the organic EL display devices each comprise a plurality of organic EL elements having different light emitting colors,
a plurality of the anode power supply wirings are provided corresponding to the organic EL elements having different light emitting colors, and
the anode power supply wiring for each light emitting color is connected to the common anode power supply wiring through a color balance adjustment resistance element having a resistance value based on the characteristics of the organic EL elements having the light emitting colors.

9. A method of testing an organic EL display device which comprises a plurality of pixels at least comprising an organic EL element, a drive TFT in which any one of a source and a drain is connected to an anode of the organic EL element, and the other of the source and the drain is connected to an anode power supply wiring, and a control TFT in which any one of a source and a drain is connected to a gate of the drive TFT, the other of the source and the drain is connected to a data wiring, and a gate is connected to a scanning wiring, a cathode of the organic EL element being connected to a cathode power supply wiring, wherein
one electrode of a capacitative element is connected to the gate of the drive TFT,
a test signal is input from the other electrode of the capacitative element, and
a test anode voltage and a test cathode voltage are applied respectively to the anode power supply wiring and the cathode power supply wiring, whereby each of the pixels is lighted and driven.

10. An organic EL display device comprising a plurality of pixels which at least comprise an organic EL element, a drive TFT in which any one of a source and a drain is connected to an anode of the organic EL element, and the other of the source and the drain is connected to an anode power supply wiring, a control TFT in which any one of a source and a drain is connected to a gate of the drive TFT, the other of the source and the drain is connected to a data wiring, and a gate is connected to a scanning wiring, and a capacitative element of which one electrode is connected to the gate of the drive TFT,
wherein a cathode of the organic EL element is connected to a cathode power supply wiring, and
the other electrode of the capacitative element is connected to the anode power supply wiring outside the pixel.
